(19) United States
(12) Patent Application Publication
(10) Pub. No.: US 2010/0149774 A1
(43) Pub. Date: Jun. 17, 2010

(54) SEMICONDUCTOR DEVICE

(75) Inventors: Masafumi Matsumoto, Tokyo (JP); Yuji Miyazaki, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/467,663

(22) Filed: May 18, 2009

(30) Foreign Application Priority Data
Dec. 17, 2008 (JP) 2008-320384

(51) Int. Cl. H05K 1/02

(52) U.S. Cl. 361/783; 361/777

(57) ABSTRACT

A semiconductor device includes a terminal case containing a semiconductor element, a plurality of pin terminals of equal length mounted in the terminal case and electrically connected to the semiconductor element, the plurality of pin terminals projecting outward from a predetermined surface of the terminal case in the same direction, and at least one protruding pin terminal mounted in the terminal case and projecting outward from the predetermined surface of the terminal case in the same direction farther than the plurality of pin terminals.

### BACKGROUND OF THE INVENTION

1. Field of the Invention

The present invention relates to a semiconductor device with pin terminals for insertion into throughholes in a substrate.

2. Background Art

There is a practice of packaging a plurality of semiconductor elements in a case with pin terminals, forming a modularized semiconductor device. This semiconductor device is mounted on a printed board by inserting the pin terminals of its case into throughholes in the printed board. These pin terminals are then soldered to the printed board to secure the semiconductor device to the board.

Examples of such modularized semiconductor devices with pin terminals include power modules, and it is common to mount these modules on a printed board by the method described above. For example, power modules with pin terminals containing an IGBT (Insulated Gate Bipolar Transistor), an inverter, or a converter are often mounted on a printed board by inserting the pin terminals into the printed board. Further, there are semiconductor devices called IPMs (Intelligent Power Modules) in which a power module, drive circuitry, etc. are packaged in a single package. These semiconductor devices (IPMs) are also often mounted on a printed board by inserting pin terminals as described above, and are widely used since they are easy to use and enable reduction of overall device size.

When mounting a modularized semiconductor device having many pin terminals of equal length to a printed board, it has sometimes been found difficult to insert these pin terminals into throughholes in the printed board. To facilitate the insertion, many such semiconductor devices include so-called guide pins which project outward from the device farther than the pin terminals. A semiconductor device, namely, a power module, having guide pins is described in Japanese Laid-Open Patent Publication No. 05-94854 (1993). This power module is mounted on a substrate by first inserting the guide pins into guide pin holes in the substrate and then inserting the pin terminals into throughholes in the substrate. These guide pins serve to guide the pin terminals into the throughholes in the substrate, thereby facilitating the mounting of the power module. Other prior art includes Japanese Laid-Open Patent Publication Nos. 8-7956 (1996), 2000-223621, and 2004-186476 and Japanese Utility Model Patent Publication No. 7-53408 (1995).

As described above, when mounting a semiconductor device with many pin terminals of equal length to a substrate, it is difficult to align these pin terminals with throughholes in the substrate, resulting in reduced productivity. To overcome this problem, guide pins such as described above may be used to facilitate the mounting. However, the use of guide pins prevents the semiconductor device from being reduced in size and cost.

### SUMMARY OF THE INVENTION

The present invention has been made to solve the above problems. It is, therefore, an object of the present invention to provide a semiconductor device with pin terminals and having a construction that facilitates the alignment of these pin terminals with throughholes in the substrate on which the semiconductor device is mounted and thereby facilitates the mounting, and that allows the semiconductor device to be reduced in size and cost.

According to one aspect of the present invention, a semiconductor device includes, a terminal case containing a semiconductor element, a plurality of pin terminals of equal length mounted in the terminal case and electrically connected to the semiconductor element, the plurality of pin terminals projecting outward from a predetermined surface of the terminal case in the same direction, and at least one protruding pin terminal mounted in the terminal case and projecting outward from the predetermined surface of the terminal case in the same direction farther than the plurality of pin terminals.

Other and further objects, features and advantages of the invention will appear more fully from the following description.

### BRIEF DESCRIPTION OF THE DRAWINGS

FIG. 1 is a perspective view of the semiconductor device of the embodiment;

FIG. 2 is a diagram illustrating alignment of the semiconductor device with a substrate preparatory to mounting the device to the substrate;

FIG. 3 shows a semiconductor device including four protruding pin terminals, each disposed at a respective corner of the rectangular top surface of the terminal case;

FIG. 4 shows protruding pin terminals respectively disposed at both ends of the line of pin terminals;

FIG. 5 shows protruding pin terminals respectively mounted at the other two corners of the rectangular top surface of the terminal case; and

FIG. 6 shows protruding pin terminal which has no electrical function.

### DETAILED DESCRIPTION OF THE PREFERRED EMBODIMENT

### Embodiment

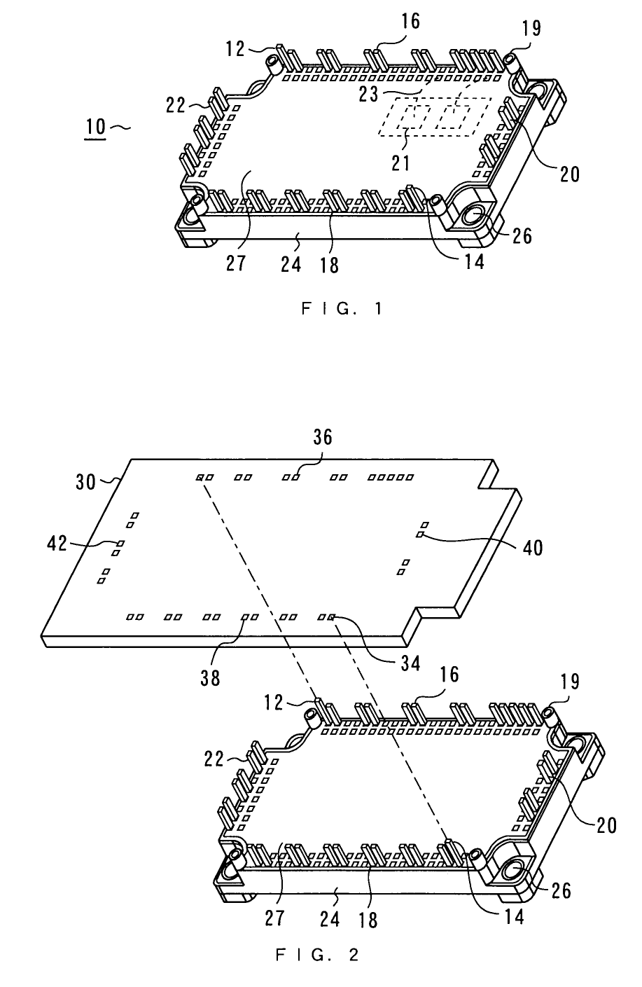

An embodiment of the present invention will be described with reference to FIGS. 1 to 6. It should be noted that like numerals represent like materials or like or corresponding components, and these materials and components may be described only once.

FIG. 1 is a perspective view of a semiconductor device 10 of the present embodiment. The semiconductor device 10 includes a boxy terminal case 24 of, e.g., resin in which semiconductor elements and pin terminals (described below) can be mounted. According to the present embodiment, the terminal case 24 contains a plurality of semiconductor elements 21 and a cover 27 which covers the elements 21. These semiconductor elements 21 are not externally visible and are shown in dashed line for convenience of illustration. The semiconductor elements 21 of the present embodiment are typically, but not limited to, IGBTs and their control circuits.

Each semiconductor element 21 is connected to a respective pin terminal 16 by a wire 23 (shown in dashed line as is the semiconductor element 21). The pin terminals 16 are used to connect the semiconductor elements 21 to an external device or circuit. According to the present embodiment, pin terminals (including the pin terminals 16) are mounted in the terminal case 24 and arranged along the four sides of its rectangular top surface, as shown in FIG. 1. Reference numerals 16, 18, 20, and 22 each denote a plurality of pin terminals arranged along a respective side of the top surface of the terminal case.

These pin terminals 16, 18, 20, and 22, which are each arranged along a respective side of the rectangular top surface of the terminal case 24, are of equal length. They project an equal distance outward from the terminal case 24 in the same direction. After the semiconductor device is mounted, the pin terminals 16, 18, 20, and 22 are electrically connected to an external device or circuit to transmit signals thereto, etc.

The semiconductor device 10 of the present embodiment has protruding pin terminals 12 and 14 in addition to the pin terminals 16, 18, 20, and 22 described above. The protruding pin terminals 12 and 14 project outward from the top surface of the terminal case 24 in the same direction as, but farther than, the pin terminals 16, 18, 20, and 22. The protruding pin terminal 12 is located at one end of the line of pin terminals 16 (i.e., mounted at one end of the side of the top surface of the terminal case 24 along which the pin terminals 16 are arranged), while the protruding pin terminal 14 is located at one end of the line of pin terminals 18 (i.e., mounted at one end of the side of the top surface along which the pin terminals 18 are arranged). More specifically, these protruding pin terminals 12 and 14 are disposed at substantially diagonal corners of the rectangular top surface of the terminal case 24, as shown in FIG. 2.

After the semiconductor device 10 is mounted, the protruding pin terminals 12 and 14 are electrically connected to an external device or circuit to transmit signals thereto, etc.

The semiconductor device 10 also includes pedestals 19 for supporting a substrate, and mounting holes 26 for mounting a heat sink, etc. on the back surface of the semiconductor device 10. This completes the description of the configuration of the semiconductor device 10 of the present embodiment.

FIG. 2 is a diagram illustrating alignment of the semiconductor device 10 with a substrate 30 preparatory to mounting the device to the substrate. As shown in FIG. 2, the substrate 30 has formed therein protruding pin terminal throughholes 32 and 34 and pluralities of throughholes 36, 38, 40, and 42. The throughholes 36, 38, 40, and 42 are each arranged in a line and positioned and adapted to receive the pin terminals 16, 18, 20, and 22, respectively, of the semiconductor device 10. The semiconductor device 10 is mounted on the substrate 30 in the following manner. First, the protruding pin terminals 12 and 14 of the semiconductor device 10 are inserted into the protruding pin terminal throughholes 32 and 34, respectively, in the substrate 30 to accurately align the semiconductor device 10 with the substrate 30. Next, the pin terminals 16, 18, 20, and 22 are inserted into the throughholes 36, 38, 40, and 42. The protruding pin terminals 12 and 14 and the pin terminals 16, 18, 20, and 22 are then soldered to the substrate 30, thus completing the mounting of the semiconductor device 10 to the substrate 30. It should be noted that the protruding pin terminal throughholes 32 and 34 and the throughholes 36, 38, 40, and 42 are all of the same diameter; these throughholes are substantially the same although they are referenced herein by different reference numerals for convenience of illustration.

It has been found that when inserting many pin terminals of equal length into throughholes in a substrate it is difficult to align these pin terminals with the throughholes, resulting in reduced productivity. The reason for this is that all of the pin terminals must be aligned and inserted into the throughholes at once. The semiconductor device 10 of the present embodiment is constructed to avoid this problem. Specifically, when the semiconductor device 10 is mounted on the substrate 30, the protruding pin terminals 12 and 14 are first inserted into the protruding pin terminal throughholes 32 and 34, thereby completing the alignment of the semiconductor device 10 with the substrate 30. It will be noted that it is easy to insert two pin terminals into throughholes. After the insertion of the protruding pin terminals 12 and 14, the pin terminals 16, 18, 20, and 22 can be readily inserted into their respective throughholes in the substrate, since the inserted protruding pin terminals 12 and 14 serve as guides for this insertion operation. Thus, the present embodiment allows semiconductor devices with many pin terminals to be easily and readily mounted.

Further, according to the present embodiment, after the semiconductor device is mounted on the substrate, both the pin terminals and the protruding pin terminals are electrically connected to the external device or circuit to which the semiconductor device transmits signals, etc. when in operation. It should be noted that some prior art semiconductor devices are provided with guide pins for facilitating their mounting to a substrate, etc. (see, e.g., Japanese Laid-Open Patent Publication No. 05-94854 noted above).

However, these guide pins are not electrically connected to any external device or circuit. They do not have any electrical function, as do the protruding pin terminals of the present embodiment. That is, the configuration of the semiconductor device of the present embodiment eliminates the need for guide pins (serving only as insertion guides) yet still allows the device to be easily and readily mounted on a substrate. This enables the semiconductor device to be reduced in size and cost, as well as eliminating the need to form guide pin throughholes in the substrate on which the device is mounted.

It will be understood that the semiconductor device of the present invention is not limited to the configuration described above, but various alterations may be made thereto. For example, the semiconductor device may include four protruding pin terminals 12, 13, 14, and 15 each disposed at a respective corner of the rectangular top surface of the terminal case 24, as shown in FIG. 3. This arrangement further improves the alignment accuracy of the semiconductor device with the substrate.

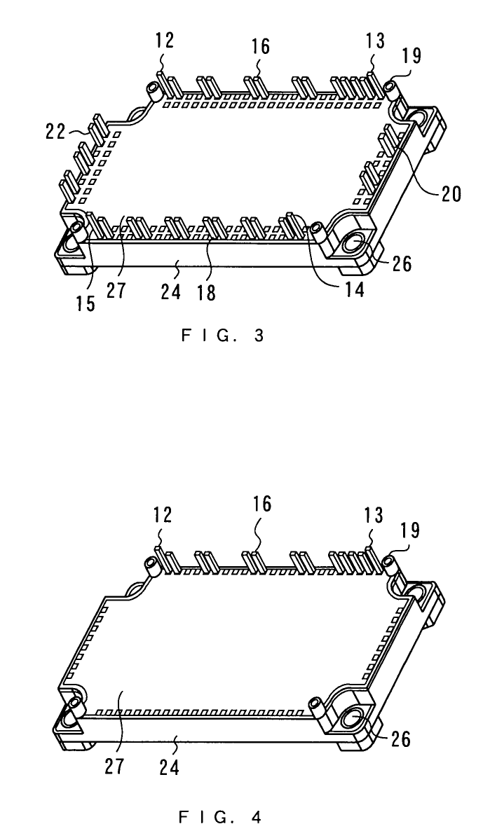

Further, the semiconductor device may be designed to have only one line of pin terminals 16. In such a case, protruding pin terminals 12 and 13 may be respectively disposed at both ends of the line of pin terminals 16 (i.e., mounted at two corners of the rectangular top surface of the terminal case 24), as shown in FIG. 4, to facilitate and quicken the mounting of the semiconductor device to the substrate. However, it may not be possible to adequately secure the semiconductor device to the substrate after the mounting, since the semiconductor device has only one line of pin terminals and does not have guide pins.

To avoid this problem, protruding pin terminals 52 and 54 may be respectively mounted at the other two corners of the rectangular top surface of the terminal case 24, as shown in FIG. 5, so that the semiconductor device can be more firmly secured to the substrate. It should be noted that like guide pins, the protruding pin terminals 52 and 54 shown in FIG. 5 only serve to facilitate the mounting of the semiconductor device on the substrate and do not receive or transmit any electrical signals. However, many semiconductor devices with pin terminals have terminal mounting spaces (or locations) for additional pin terminals so that they can be used in various applications. In such a case, protruding pin terminals may be mounted at these available locations to facilitate and quicken the mounting of the semiconductor device to the substrate. This arrangement has an advantage over the use of guide pins in that the semiconductor device can be reduced in size and cost.

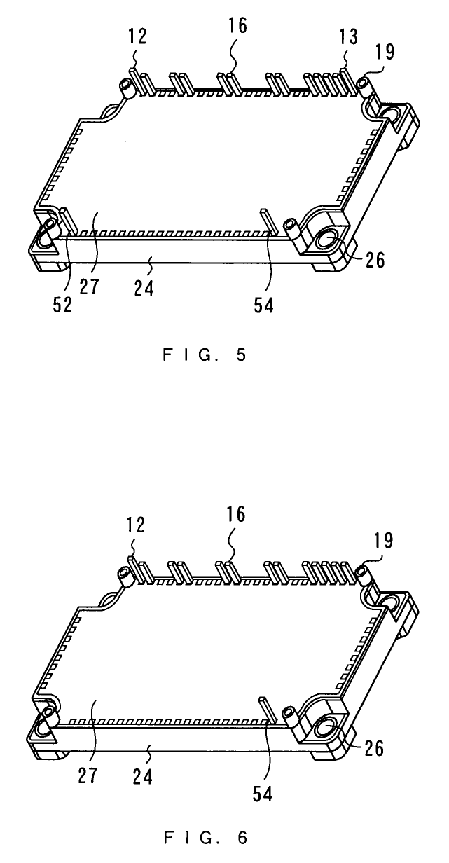

Further, in a variation of the semiconductor device of FIG. 4 having only one line of pin terminals 16, the protruding pin terminal 13 may be omitted and a protruding pin terminal 54 which has no electrical function may be additionally disposed at a location available for an additional pin terminal as described above such that the protruding pin terminal 54 is diagonally opposite to the protruding pin terminal 12, as shown in FIG. 6. This still achieves the advantages of the invention described above.

Although in the present embodiment pin terminals of equal length are mounted in the terminal case 24 and arranged along a side or sides of its rectangular top surface, it is to be understood that the present invention may be applied to other configurations. For example, the technique of the present invention may be applied to semiconductor devices in which a number of pin terminals of equal length are mounted and arranged around a center portion of the top surface of the terminal case 24, which still achieves the advantages of the invention described above, since such pin terminals are also difficult to align with the substrate into which they are inserted. Further, although in the present embodiment the top surface of the terminal case is rectangular in shape, it is to be understood that in other embodiments it may be of a different shape.

Further, various other alterations may be made to the present embodiment without departing from the scope of the present invention.

Thus the present invention enables the manufacture of a semiconductor device which is easy to mount and which is reduced in size and cost.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-320384, filed on Dec. 17, 2008 including specification, claims, drawings and summary, on which the Convention priority of the present application is based, are incorporated herein by reference in its entirety.

What is claimed is:

1. A semiconductor device comprising:
a terminal case containing a semiconductor element;
a plurality of pin terminals of equal length mounted in said terminal case and electrically connected to said semiconductor element, said plurality of pin terminals projecting outward from a predetermined surface of said terminal case in the same direction; and
at least one protruding pin terminal mounted in said terminal case and projecting outward from said predetermined surface of said terminal case in said same direction farther than said plurality of pin terminals.

2. The semiconductor device according to claim 1, wherein said at least one protruding pin terminal is electrically connected to said semiconductor element.

3. The semiconductor device according to claim 1, wherein:
said predetermined surface is rectangular in shape;
said plurality of pin terminals are arranged along sides of said rectangular surface; and
said at least one protruding pin terminal is mounted at least one end of a respective one of said sides of said rectangular surface.

4. The semiconductor device according to claim 3, wherein said at least one protruding pin terminal is mounted at diagonally opposite positions of said rectangular surface.

5. The semiconductor device according to claim 3, wherein said at least one protruding pin terminal is mounted at four corners of said rectangular surface.

6. The semiconductor device according to claim 4, wherein:
said plurality of pin terminals are arranged along one side of said rectangular surface; and
the one or ones of said at least one protruding pin terminal which are mounted at other sides of said rectangular surface are not electrically connected to said semiconductor element.
